(19) United States
(12) Patent Application Publication
(10) Pub. No.: US 2019/0034330 A1
(43) Pub. Date: Jan. 31, 2019

(54) MASS STORAGE DEVICE WITH DYNAMIC SINGLE LEVEL CELL (SLC) BUFFER SPECIFIC PROGRAM AND/OR ERASE SETTINGS

(71) Applicant: Intel Corporation, Santa Clara, CA (US)

(72) Inventors: Shankar NATARAJAN, Folsom, CA (US); Aliasgar S. MADRASWALA, Folsom, CA (US); Kristopher H. GAEWSKY, El Dorado Hills, CA (US); Jason CULP, Sacramento, CA (US)

(21) Appl. No.: 15/829,764

(22) Filed: Dec. 1, 2017

(51) Int. Cl. G06F 12/02; G11C 16/34; G11C 16/16; G11C 16/30

(52) U.S. Cl. CPC G06F 12/0246; G11C 16/349; G06F 2212/7211; G11C 16/30; G11C 16/16

(57) ABSTRACT

An apparatus is described. The apparatus includes a mass storage device having a plurality of storage cells capable of storing more than one bit per cell. The plurality of storage cells are partitionable into a static single level (SLC) buffer, a dynamic SLC buffer and a primary multi-bit storage region. The mass storage device includes charge pump circuitry to program and erase the storage cells such that: a) those of the cells associated with the SLC buffer are to maintain larger stored charge potentials than those of the cells associated with the dynamic SLC buffer; and, b) those of the cells associated with the dynamic SLC buffer, when in SLC mode, are to receive fewer charge pump cycles during a program and/or erase sequence than those of the cells associated with the primary multi-bit storage region.

### FIELD OF INVENTION

The field of invention pertains generally to the electrical engineering arts, and, more specifically, a mass storage device with dynamic SLC buffer specific trim settings.

### BACKGROUND

As computing systems become more and more powerful their storage needs to continue to grow. In response to this trend, mass storage semiconductor chip manufacturers are developing ways to store more than one bit in a storage cell. Unfortunately, such cells may demonstrate reliability weaknesses as compared to their binary storage cell predecessors. As such, mass storage device manufacturers are developing new techniques for addressing the reliability issues.

### FIGURES

A better understanding of the present invention can be obtained from the following detailed description in conjunction with the following drawings, in which:

FIG. 1 shows a solid state drive;

FIG. 2 pertains to an improved solid state drive;

FIG. 3 shows a method performed by the improved solid state drive;

FIG. 4 shows a computing system.

### DETAILED DESCRIPTION

Different FLASH memory technologies store different numbers of bits per cell. Specifically, a single level cell (SLC) stores one bit per cell, a multiple level cell (MLC) stores two bits per cell, a ternary level cell (TLC) stores three bits per cell and quad level cell (QLC) stores four bits per cell. Whereas an SLC cell is only capable of storing two logic states per cell (a “1” or a “0”), each of the MLC, TLC and QLC cell types, which may be characterized as different types of “multi-bit” storage cells, greatly expand the storage capacity of a FLASH device because more than two digital states can be stored in a single cell (e.g., four digital states can be stored in an MLC cell, eight digital states can be stored in a TLC cell and sixteen logic states can be stored in a QLC cell).

Here, a particular cell that is capable of storing more than one bit per cell (e.g., any of an MLC cell, TLC cell or QLC cell) can also operate in an SLC mode. That is, because these cells are capable of storing more than one bit per cell, they can easily be used to store only one bit per cell. Generally, each different logic state that a cell can store is realized with a different amount of charge that is stored within the cell. For example, a QLC FLASH cell is able to store sixteen separately discernable charge amounts in order to physically realize the ability to store four bits at one time. Because a QLC cell is designed to store sixteen different charge levels, it can readily operate in an SLC mode in which it only stores two different charge amounts. Similarly, MLC and TLC cells can also be operated in an SLC mode in which they only store two different charge amounts.

The SLC mode of a multi-bit cell generally has lower write access times than its multi-bit operation. Here, as described in more detail below, the writing activity in SLC mode need not be as precise for multi-bit mode. The lesser precision that is sufficient for SLC mode translates into less time needed to write digital information into the cell as compared to multi-bit write operations. As such, hybrid architecture FLASH SSDs have been implemented in which some portion of an SSD's multi-bit storage cells are deliberately placed in SLC mode to take advantage of this speed advantage.

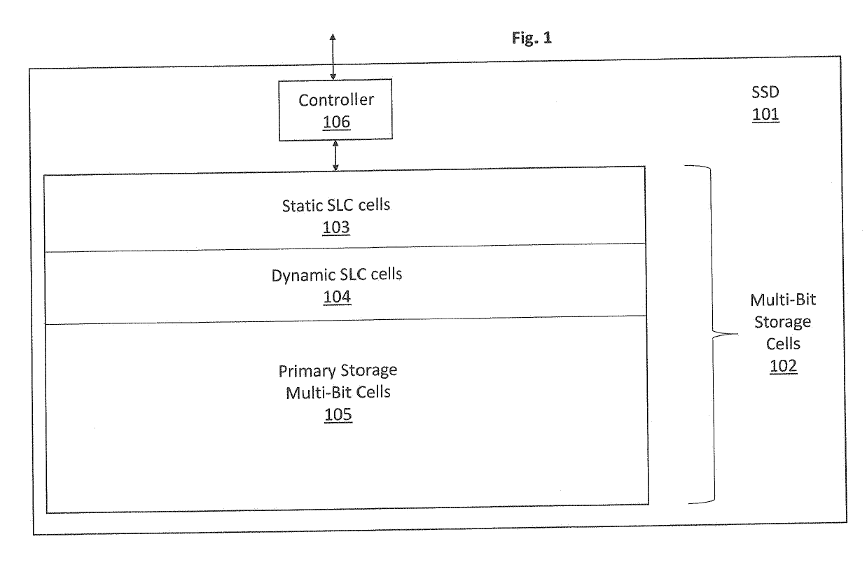

FIG. 1 shows an exemplary hybrid SSD 101. As observed in FIG. 1, the SSD 101 is composed of many multi-bit storage cells 102 (which may be realized with a plurality of multi-bit FLASH semiconductor memory chips). However, the multi-bit storage cells 102 are partitioned into: 1) a first partition of cells 103 that, even though their underlying technology is capable of multi-bit operation (e.g., MLC, TLC, QLC, etc.), are permanently or quasi-permanently placed in an SLC mode of operation; 2) a second partition of cells 104 that initially operates in SLC mode upon SSD bring-up but may, depending on user storage needs, switch-over to multi-bit operation; and, 3) a third partition of cells 105 that permanently or quasi-permanently operate in multi-bit mode.

The cells of the first partition 103 and the cells of the second partition 104 when operating in SLC mode are used to implement a “fast cache” or “buffer” that a user of the SSD 101 will observe to possess faster write access times as compared to the write access times of the primary multi-bit storage cells 105. Here, for instance, if the SDD 101 receives a burst of write accesses having effectively random addresses across the burst, the write information is written into cells of the first and/or second partitions 103, 104 that are operating in an SLC mode. By so doing, the write operations are performed more quickly and the host system (e.g., a computer to which the SSD is coupled) enjoys faster performance from the SSD 101 as a whole

The two different partitions 103, 104 correspond to two different types of SLC buffers: a static SLC buffer and a dynamic SLC buffer. More specifically, the cells of the first partition 103 correspond to a static SLC buffer and the cells of the second partition 104 correspond to a dynamic SLC buffer. The cells 103 of the static SLC buffer are essentially “extra” storage cells in the SSD (e.g., cells that extend the storage capacity of the SSD 101 beyond its stated capacity). Here, depending on implementation, information that is written into the cells 103 of the static SLC buffer may be subsequently moved to the primary multi-bit storage area 105, e.g., during a background process performed by the SSD controller 106.

In the case of the dynamic SLC buffer, rather than reserve a permanently partitioned extra capacity area of the SSD as is done with the static SLC buffer, instead, an SLC buffer is implemented with cells 104 that can operate in SLC mode to implement a fast cache buffer, or, operate in multi-bit mode as primary storage. Which mode these cells 104 operate in (SLC mode or multi-bit mode) depends on the storage load that is presented to the SSD 101.

More specifically, the cells 104 of the dynamic SLC buffer are initially (e.g., at SSD device boot-up) placed into an SLC mode whereas the cells of the primary multi-bit storage area 105 are placed in their nominal multi-bit mode. However, because the stated maximum storage capacity includes the capacity of the dynamic buffer cells 104 when they are in multi-bit mode (and therefore holding their maximum capacity of data), the cells 104 that are associated with the dynamic buffer will begin to switchover to multi-bit operation once the storage load presented to the SSD approximately compares with the capacity of the primary storage area 105.

When this threshold is reached, any additional new data to be written into the SSD (without overwriting existing data) is written to the cells 104 in the dynamic buffer in multi-bit mode which causes the size of the dynamic SLC buffer to shrink. As the amount of data stored by the SSD 101 wavers above and below this threshold, the cells 104 that are assigned to the dynamic SLC buffer will transition back-and-forth between SLC mode and multi-bit mode. That is, if after surpassing the threshold, the amount of stored data falls below the threshold, any “freed up” dynamic SLC cells (i.e., dynamic cells that were converted to multi-bit mode) can covert back to SLC mode to “recapture” previously lost dynamic SLC buffer size. Thus, the size of the dynamic SLC buffer can shrink and expand depending on the amount of data that the SSD device 101 is storing.

The cells 103 of the static buffer SLC cells are therefore treated differently than the cells 104 of the dynamic buffer. Whereas static buffer SLC cells 103 remain in SLC mode for their entire lifetime (or almost their entire lifetime), by contrast, dynamic buffer cells 104 may dynamically switch back and forth between SLC mode and multi-bit mode. Because different programming and/or erase voltage settings and/or associated timings (e.g., number of charge pump cycles) (“trims”) are associated with the two modes, the different types of buffer cells are essentially subjected to different environments. As such, they may wear-out differently.

Problematically, existing hybrid architecture SSD devices are believed to apply same SLC trims to both the cells 103 of the static SLC buffer and the cells 104 of the dynamic SLC buffer. As a consequence, the cells 104 of the dynamic SLC buffer while demonstrate more rapid degradation than the main storage multi-bit cells 105. Therefore, according to an improved hybrid SSD design, the cells 103 of the static SLC buffer are programmed/erased according to first trim characteristics and the cells 104 of the dynamic SLC buffer are programmed/erased according second trim characteristics where the first and second trim characteristics are different.

Simplistically, a FLASH cell includes a dielectric (e.g., oxide) that is used to store the charge that is interpreted as the cell's stored digital information. Whenever a FLASH cell is programmed or erased the dielectric is degraded. Eventually, after a certain number of program and erase sequences have been applied to the FLASH cell, the dielectric will not be capable of reliably storing the information that is written to it. Here, generally, the reliability of multi-bit FLASH cells (e.g., MLC, TLC, QLC) are more sensitive to degradation of their dielectric than SLC cells.

Multi-bit FLASH cells can be seen as having tighter charge storage tolerances than SLC cells. That is, because more than two logical states can be stored in a multi-bit cell, whereas an SLC cell only stores two logical states, a multi-bit cell has smaller amounts of charge differentiating between the different logical states it can store. With the degradation of a cell's dielectric being approximately characterized as an increasing inability to store charge with precision, a multi-bit cell will generally become unreliable before an SLC cell will become unreliable for a same amount of dielectric degradation.

A FLASH cell is programmed or erased by pumping it with charge. SLC cells, having a greater difference between its pair of stored charge states than multi-bit cells, uses a more “coarse-grained” pumping process that applies larger charge increments in fewer pump cycles than a multi-bit cell which uses a more “fine-grained” pumping process that applies smaller charge increments over more pump cycles (at least for its largest pumped charge amounts). The fewer pump cycles associated with an SLC cell is what causes an SLC cell to have reduced write access times as compared to a multi-bit cell and provides the basis for the faster cache like behavior with the static and dynamic SLC buffers.

As mentioned above, existing hybrid SSD devices are believed to apply a standard SLC pumping process (fewer pumps with larger charge increments per pump) to both the cells 103 of the static SLC buffer and the cells 104 of the dynamic SLC buffer. However, regular application of the larger potentials used to effect the larger charge amounts, by themselves, will induce more damage to a FLASH cell's dielectric than the application of the smaller potentials used to effect the smaller charge increments associated with multi-bit write pumping processes. As such, the more aggressive, coarse-grained pumping approach that is applied to an SLC cell will degrade the SLC cell's dielectric more substantially with each program/erase cycle as compared to the damage that is induced to a multi-bit cell by the multi-bit cell's more gentle, finer grained pumping technique.

Importantly, sensitivity to dielectric degradation is different than inducing dielectric degradation. Thus, in existing SSDs, the cells 104 of the dynamic SLC buffer will reach wear-out sooner than the primary storage multi-bit cells 105 that are not operated in an SLC mode. Thus, when the dynamic SLC cells 104 switch-over to multi-bit mode, having greater damage to their dielectric on account of their SLC activity and with enhanced sensitivity to such damage with their new operation in multi-bit mode, the cells 104 of the dynamic SLC buffer will generally become unreliable after fewer program/erase cycles than the primary multi-bit storage cells 105.

A solution therefore is to program the cells 104 of the dynamic SLC buffer with reduced voltage potential(s) as compared to the cells 103 of the static SLC buffer and with fewer pump cycles as compared to the cells 105 of the primary storage area 105 (at least for the higher charge states obtained by the multi-bit cells). The reduced voltage potential(s) minimizes dielectric damage to the cells 104 of the dynamic buffer when operating in SLC mode (or at least imparts damage that is more comparable to multi-bit use). The fewer pump cycles provide the reduced access times (as compared to multi-bit operation) that are desired for SLC operation.

With less voltage potential than a static SLC cell and fewer pumps than the number of pump steps used to reach a multi-bit cell's largest accumulated charge states, the charge difference between the two states held by a dynamic buffer SLC cell 104 when operating in SLC mode will be less than is typical for SLC operation but nevertheless may be comparable to two neighboring, lowest potential states in multi-bit operation. As such, any noise margin error that results from applying less potential in SLC mode should be in-line with standard multi-bit operation and therefore correctable with the SSD's existing error correction code (ECC) coverage.

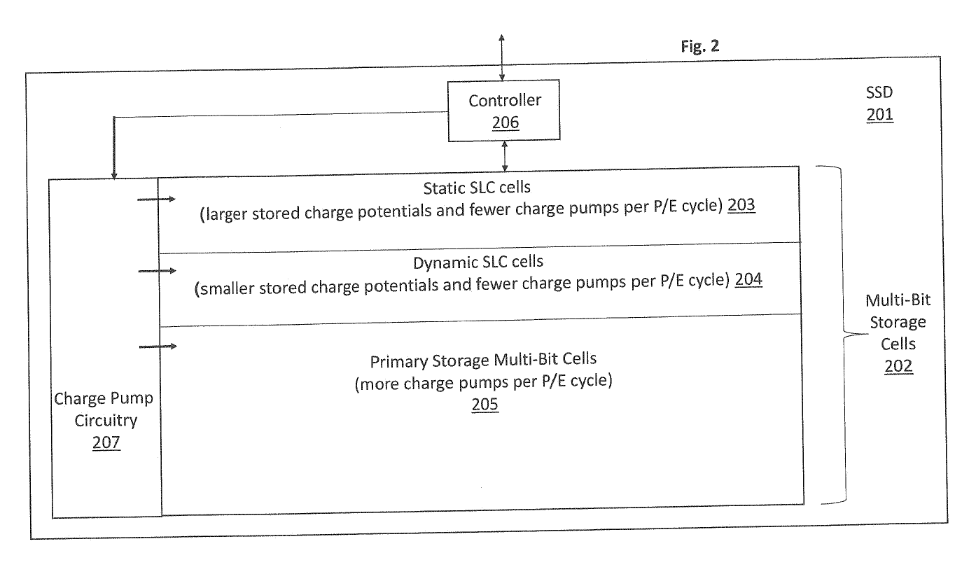

FIG. 2 depicts a high level view of a hybrid architecture SSD device having a static SLC buffer and a dynamic SLC buffer as described above. In particular FIG. 2 shows qualitative descriptions of the different trim settings for the different cells in the SSD device. Here, in various embodiments, the storage cells are multi-bit storage cells disposed on one or more FLASH memory chips within the SSD. As can be seen in FIG. 2, the storage cells 203 that are used to implement the static SLC buffer have larger stored charge potentials than the cells 204 that are used to implement the dynamic SLC buffer.

In an embodiment, the storage cells 203 of the static SLC buffer 203 are provided program and erase voltages whose starting (initial) absolute values are greater than the starting absolute values of the program and erase voltages that are provided to the cells 204 that are used to implement the dynamic SLC buffer. By using lower initial/starting potentials for the charge pumping activity that is applied to the cells 204 of the dynamic SLC buffer, when operating in SLC mode at least, the cells 204 will maintain stored binary states having lower stored charge/potential than the static SLC cells 203. Here, in various embodiments, the number of charge pump cycles needed to reach a particular binary state is the same and/or is approximately the same as between the static SLC cells 203 and the dynamic SLC buffer cells 204 when the later are operating in SLC mode. Keeping the number of pump cycles/steps the same/comparable for the two different types of SLC cells should keep their access times approximately equal.

Similarly, in various embodiments, the number of pump cycles/steps for SLC activity (whether a static SLC cell 203 or a dynamic SLC buffer cell 204 operating in SLC mode) is less than the number of steps applied to primary multi-bit storage cells 205 (at least for the higher stored charge/potential states reached by the primary multi-bit cells 205) to ensure that the cells of the SLC buffers (whether a static or dynamic) have lower access times than the primary multi-bit cells 205 on average. Further still, the static SLC cells 203 and dynamic SLC cells 204, when the later are operating in SLC mode, may receive larger charge increments per pump cycle/step than the multi-bit cells 205 to effect faster SLC write times (by reaching their target potential/charge sooner).

Thus, both the storage cells 203 that are used to implement the static SLC buffer and the storage cells 204 that are used to implement the dynamic SLC buffer, when the later are operating in SLC mode, in various embodiments, are subjected to fewer charge pump cycles and greater charge increment per pump cycle during programming and/or erasure than the cells 205 that are used to implement the SSD's primary storage area.

In various embodiments, when the storage cells 204 that are used to implement the dynamic SLC buffer switch over to multi-bit operation, they are subjected to the same programming and/or erasure voltages and/or number of charge pump cycles during programming and/or erasure as the cells 205 associated with the primary storage area. FIG. 2 shows charge pump circuitry 207 that is controlled by the controller 206 to effect program and/or erase voltage settings and associated timings (e.g., starting potential, charge increment per program and/or erase charge pump cycle and number of charge pump cycles per program and/or erase sequence) for the different regions 203, 204, 205 that are consistent with the characteristics described immediately above.

As discussed above, the pair of stored charge/potential levels used by the cells 204 of the dynamic SLC buffer, when operating in SLC mode, may be comparable to the two lowest stored charge levels used by the cells 205 of the primary storage area. With these improvements over existing SSD devices, it is conceivable that the cells of the dynamic buffer 204 may last the lifetime of the SSD (unlike existing SSD devices which are believed to “turn-off” the dynamic buffer activity after a certain amount of data has been written into the SSD 201).

Although not shown in FIG. 2, some additional multi-bit cells of the SSD 201 may be used to implement system blocks. Here, system blocks are blocks of cells that are used to store, e.g., basic input/output system (BIOS) firmware. As such some percentage of these cells may even mimic/emulate a read-only-memory (ROM) and therefore are subjected to very few write over their lifetime (e.g., they mimic write-once storage resource). Other system cells may be written to more frequently.

Additionally, in various embodiments, the respective cells of the different regions 203, 204, 205 of FIG. 2 are wear leveled independently. Here, the SSD controller 206 dynamically remaps host block addresses (also referred to as logical block addresses (LBAs)) to physical block addresses where information is actually stored within the SSD 201. Storage cells that are written to more frequently will wear-out faster than cells that are written to less frequently. The SSD controller 206 therefore performs wear leveling to remap “hot” blocks of information that are frequently accessed to “colder” blocks that have only been infrequently accessed (the information in the colder blocks may also be swapped into the hot blocks).

Here, the controller 206 monitors the access rates (and/or total accesses) for the SSD's physical addresses and maintains an internal map that maps these physical addresses to the host block addresses that are provided to the SSD by the host. Based on the monitored rates and/or counts the controller 206 determines when certain blocks are deemed to be “hot” and need to have their associate data swapped out, and, determines when certain blocks are deemed “cold” and can receive hot blocks of data (the different regions 203, 204, 205 may also have an extra percentage of additional cells beyond the recognized capacity of these regions so that there should always be some supply of “cold” blocks).

In an embodiment of the SSD 201 of FIG. 2, the controller executes different wear-leveling algorithms for the different regions 203, 204, 205. Here, as described above, since the cells of the respective regions 203, 204, 205 are subjected to different use treatments (region 203 is SLC operation only, region 204 is a combination of SLC and multi-bit operation, region 205 is multi-bit operation only) they are apt to wear-out differently. More specifically, the rates/numbers of accesses at which a block's cells become “hot” are apt to be different across each of the regions. Additionally, for region 204, the controller may keep a pair of access rates/counts for the cells of each block (one access rate/count of SLC accesses and one access rate/count of multi-bit accesses).

Alternatively or in combination, any movement of a hot block to a cold block is kept within the boundaries of like cells. That is, a hot block of static SLC cells can only be moved to another block of cells within the static SLC region 203; a hot block of cells within the dynamic buffer region 204 can only be moved to another block of cells within the dynamic buffer region 203; and, a hot block of primary multi-bit storage cells in region 205 can only be moved to another block of cells within the primary multi-bit storage region 205.

Finally, since regions 203 and 204 are supposed to be akin to fast caches/buffers, the controller may swap out data that is stored in these regions and write them into the primary storage area 205 to ensure room in the buffers for subsequent write requests. However, if some system block addresses are frequently being written to (as measured by the controller 206), the controller 206 may decide to keep their corresponding data in the buffers so that true cache like behavior is effected.

In other embodiments, the sizes of the static SLC buffer 203 and/or dynamic SLC buffer 204 are made configurable by the user. According to one embodiment, the amount of storage capacity that is allocated to the static SLC buffer 203 and the dynamic SLC buffer is fixed but the user can configure how much of this capacity it to be allocated to the static SLC buffer 203 and how much of this capacity is to be allocated to the dynamic SLC buffer 204. During power-on/reset, all of these cells are brought-up as dynamic SLC cells are so are initially configured to receive dynamic SLC cell trims. After the user specifies the capacity of the static SLC buffer, a corresponding number of these cells (e.g., a corresponding number of blocks that contain these cells) have their trims changed to the trims that are to be used for the static SLC buffer. In a further embodiment, the default mode of the SSD 201 is to have a static SLC buffer size of zero (it does not exist) unless the user specifically programs the SSD 201 to include it. In various embodiments, the controller 206 controls the programming as applied to the SSD from user, establishes the size of the static and dynamic buffers 203, 204 and applies the correct trims to the specific blocks who are associated with the different regions 203, 204, 205 in the device.

The controller 206 may be implemented with logic circuitry that is designed to execute some form of program code (e.g., a micro-controller, an embedded processor, etc.), custom hardwired logic circuitry or programmable logic circuitry (e.g., an FPGA or PLD) or any combination thereof. The controller may be integrated on a same semiconductor chip as the charge pump circuitry 207. The charge pump circuitry may be integrated on a same semiconductor chip with the storage cells and/or the controller 207. Alternatively or in combination, the controller 206 and/or charge pump circuitry may be integrated on a peripheral controller or memory controller of, e.g., a large system on chip semiconductor chip having, e.g., multiple processing cores.

Also, to the extent other non volatile memory technologies besides FLASH may store more than one bit per cell and exhibit degradation mechanisms that are analogous to the mechanisms described above, conceivably, the teachings provided above may also be applicable to storage devices composed of such alternative technologies. Such alternative technologies might include memory technologies having storage cells composed of chalcogenide, resistive memories (RRAM), Ferroelectric memories (FeRAM), magnetic memories (MRAM), etc.

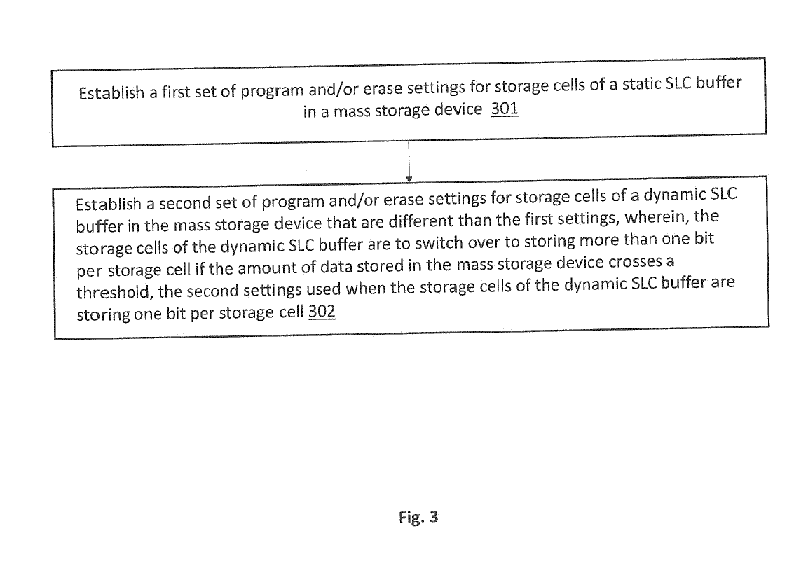

FIG. 3 shows a method described above. The method includes establishing 301 a first set of program and/or erase settings for storage cells of a static SLC buffer in a mass storage device. The method also includes establishing 302 a second set of program and/or erase settings for storage cells of a dynamic SLC buffer in the mass storage device that are different than the first settings, wherein, the storage cells of the dynamic SLC buffer are to switch over to storing more than one bit per storage cell if the amount of data stored in the mass storage device crosses a threshold, the second settings used when the storage cells of the dynamic SLC buffer are storing one bit per storage cell.

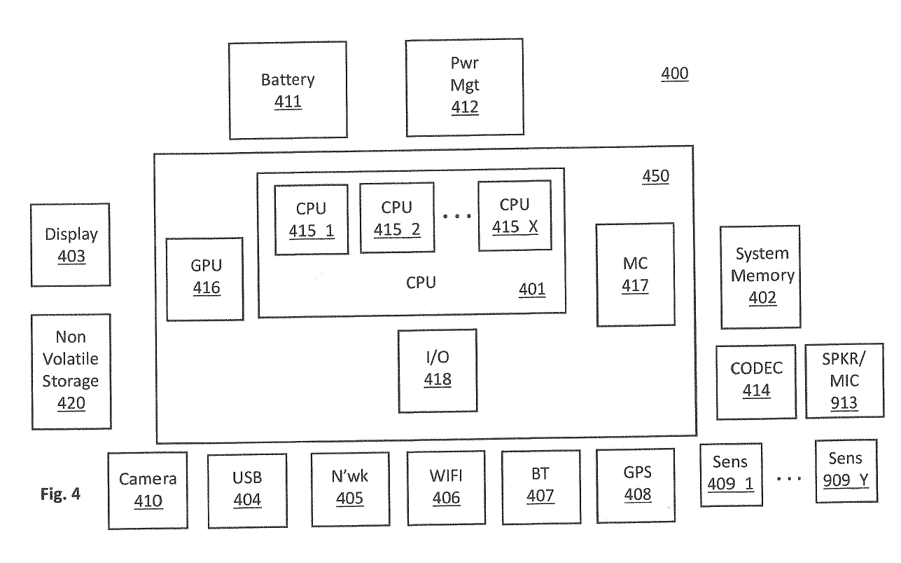

FIG. 4 provides an exemplary depiction of a computing system 400 (e.g., a smartphone, a tablet computer, a laptop computer, a desktop computer, a server computer, etc.). As observed in FIG. 4, the basic computing system 400 may include a central processing unit 401 (which may include, e.g., a plurality of general purpose processing cores 415_1 through 415_X) and a main memory controller 417 disposed on a multi-core processor or applications processor, system memory 402, a display 403 (e.g., touchscreen, flat-panel), a local wired point-to-point link (e.g., USB) interface 404, various network I/O functions 405 (such as an Ethernet interface and/or cellular modem subsystem), a wireless local area network (e.g., WiFi) interface 406, a wireless point-to-point link (e.g., Bluetooth) interface 407 and a Global Positioning System interface 408, various sensors 409_1 through 409_Y, one or more cameras 410, a battery 411, a power management control unit 412, a speaker and microphone 413 and an audio coder/decoder 414.

An applications processor or multi-core processor 450 may include one or more general purpose processing cores 415 within its CPU 401, one or more graphical processing units 416, a memory management function 417 (e.g., a memory controller) and an I/O control function 418. The general purpose processing cores 415 typically execute the operating system and application software of the computing system. The graphics processing unit 416 typically executes graphics intensive functions to, e.g., generate graphics information that is presented on the display 403. The memory control function 417 interfaces with the system memory 402 to write/read data to/from system memory 402. The power management control unit 412 generally controls the power consumption of the system 400.

Each of the touchscreen display 403, the communication interfaces 404-707, the GPS interface 408, the sensors 409, the camera(s) 410, and the speaker/microphone codec 413, 414 all can be viewed as various forms of I/O (input and/or output) relative to the overall computing system including, where appropriate, an integrated peripheral device as well (e.g., the one or more cameras 410). Depending on implementation, various ones of these I/O components may be integrated on the applications processor/multi-core processor 450 or may be located off the die or outside the package of the applications processor/multi-core processor 450.

The computing system also includes non-volatile storage 420 which may be the mass storage component of the system. Here, for example, one or more SSDs composed of multi-bit storage cells having different trim settings for each of a static SLC buffer, a dynamic SLC buffer and a primary mass storage area as described at length above may be used to implement non-volatile storage 420.

Embodiments of the invention may include various processes as set forth above. The processes may be embodied in machine-executable instructions. The instructions can be used to cause a general-purpose or special-purpose processor to perform certain processes. Alternatively, these processes may be performed by specific/custom hardware components that contain hardwired logic circuitry or programmable logic circuitry (e.g., FPGA, PLD) for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed:

1. An apparatus, comprising:
a mass storage device comprising a plurality of storage cells capable of storing more than one bit per cell, the plurality of storage cells being partitionable into a static single level (SLC) buffer, a dynamic SLC buffer and a primary multi-bit storage region, the mass storage device comprising charge pump circuitry to program and erase the storage cells such that:
a) those of the cells associated with the SLC buffer are to maintain larger stored charge potentials than those of the cells associated with the dynamic SLC buffer;
b) those of the cells associated with the dynamic SLC buffer, when in SLC mode, are to receive fewer charge pump cycles during a program and/or erase sequence than those of the cells associated with the primary multi-bit storage region.

2. The apparatus of claim 1 wherein the storage cells are ternary level cells.

3. The apparatus of claim 1 wherein the storage cells are quad level cells.

4. The apparatus of claim 1 wherein the dynamic SLC buffer has a lifetime that is comparable to the primary multi-bit storage region.

5. The apparatus of claim 1 further comprising controller circuitry to implement different wear leveling algorithms for each of:
those of the cells associated with the static SLC buffer;
those of the cells associated with the cells of the dynamic SLC buffer;
those of the cells associated with the cells of the primary multi-bit storage region.

6. The apparatus of claim 5 further comprising controller circuitry to:
move a hot block within the SLC buffer only to another block within the SLC buffer;
move a hot block within the dynamic SLC buffer only to another block within the dynamic SLC buffer;
move a hot block within the primary multi-bit storage region only to another block within the primary multi-bit storage region.

7. The apparatus of claim 1 wherein the controller supports a configuration of the solid state drive in which the static SLC buffer does not exist.

8. A computing system, comprising:
a plurality of processing cores;
a main memory;
a main memory controller coupled between the plurality of processing cores and the main memory controller;
a mass storage device, the mass storage device comprising a plurality of storage cells capable of storing more than one bit per cell, the plurality of storage cells being partitionable into a static single level (SLC) buffer, a dynamic SLC buffer and a primary multi-bit storage region, the solid state drive comprising charge pump circuitry to program and erase the storage cells such that:
a) those of the cells associated with the SLC buffer are to maintain larger stored charge potentials than those of the cells associated with the dynamic SLC buffer;
b) those of the cells associated with the dynamic SLC buffer, when in SLC mode, are to receive fewer charge pump cycles during a program and/or erase sequence than those of the cells associated with the primary multi-bit storage region.

9. The apparatus of claim 8 wherein the storage cells are ternary level cells.

10. The apparatus of claim 8 wherein the storage cells are quad level cells.

11. The apparatus of claim 8 wherein the dynamic SLC buffer has a lifetime that is comparable to the primary multi-bit storage region.

12. The apparatus of claim 8 wherein the solid state drive further comprises controller circuitry coupled to charge pump circuitry.

13. The apparatus of claim 12 wherein the controller circuitry is to implement different wear leveling algorithms for each of:
those of the cells associated with the static SLC buffer;
those of the cells associated with the cells of the dynamic SLC buffer;
those of the cells associated with the cells of the primary multi-bit storage region.

14. The apparatus of claim 8 wherein the controller supports a configuration of the solid state drive in which the static SLC buffer does not exist.

15. A method, comprising:
establishing a first set of program and/or erase settings for storage cells of a static SLC buffer in a mass storage device;
establishing a second set of program and/or erase settings for storage cells of a dynamic SLC buffer in the mass storage device that are different than the first settings, wherein, the storage cells of the dynamic SLC buffer are to switch over to storing more than one bit per storage cell if the amount of data stored in the mass storage device crosses a threshold, the second settings used when the storage cells of the dynamic SLC buffer are storing one bit per storage cell.

16. The method of claim 15 further comprising establishing a third set of program and/or erase settings for a primary mass storage area in the mass storage device that are different than the first and second settings, the primary mass storage area to store more than one bit per storage cell.

17. The method of claim 15 wherein the first settings comprise larger stored charge potentials than the second settings and the first and second settings comprise fewer charge pump cycles than the third settings.

18. The method of claim 15 wherein the storage cells of the primary mass storage area are ternary level cells.

19. The method of claim 15 wherein the storage cells of the primary mass storage area are quad level cells.

20. The method of claim 15 wherein storage cells of the dynamic SLC buffer have a lifetime that is comparable to storage cells of the primary mass storage area.

21. An apparatus, comprising:
charge pump circuitry to program and/or erase a plurality of storage cells capable of storing more than one bit per cell, the plurality of storage cells being partitionable into a static single level (SLC) buffer, a dynamic SLC buffer and a primary multi-bit storage region, the charge pump circuitry to program and erase the plurality of storage cells such that:
a) those of the cells associated with the SLC buffer are to maintain larger stored charge potentials than those of the cells associated with the dynamic SLC buffer;
b) those of the cells associated with the dynamic SLC buffer, when in SLC mode, are to receive fewer charge pump cycles during a program and/or erase sequence than those of the cells associated with the primary multi-bit storage region.

22. The apparatus of claim 21 wherein the storage cells are FLASH storage cells.
